(19) United States
(12) Patent Application Publication
(10) Pub. No.: US 2014/0083489 A1
(43) Pub. Date: Mar. 27, 2014

(54) SOLAR CELL, SOLAR CELL MODULE AND METHOD OF MAKING THE SOLAR CELL

(71) Applicant: MOTECH INDUSTRIES INC., New Taipei City (TW)

(72) Inventors: Kuang-Chieh Lai, New Taipei City (TW); Shih-Hsien Huang, Kaohsiung City (TW)

(73) Assignee: MOTECH INDUSTRIES INC., New Taipei City (TW)

(21) Appl. No.: 14/037,877

(22) Filed: Sep. 26, 2013

(30) Foreign Application Priority Data
Sep. 27, 2012 (TW) 101135625

(51) Int. Cl. H01L 31/0224; H01L 31/042; H01L 31/18; H01L 31/0236

(52) U.S. Cl. CPC H01L 31/022441; H01L 31/02366; H01L 31/0424; H01L 31/18
USPC 136/251; 136/256; 438/71

(57) ABSTRACT

A solar cell includes: a semiconductor substrate having a back surface with a first doped region and a second doped region, the back surface being roughened to forma roughened region; a dielectric layer disposed on the back surface; a first electrode having a first surface conforming to the shape of the back surface; and a second electrode having a second surface conforming to the shape of the back surface.

### RELATED APPLICATION

This application claims priority of Taiwanese Patent Application no. 101135625, filed on Sep. 27, 2012, which is hereby incorporated by reference in its entirety.

### FIELD OF THE INVENTION

This invention relates to a solar cell, a solar cell module and a method of making the solar cell, more particularly to a solar cell including first and second electrodes with irregularities for scattering light.

### BACKGROUND OF THE INVENTION

FIG. 1 illustrates an interdigitated back contact solar cell that includes a N-type substrate 11 having a photo-receiving surface 111, a N⁺-type semiconductor region 12 extending inwardly of the N-type substrate 11 from the photo-receiving surface 111, an anti-reflection layer 13 formed on the N⁺-type semiconductor region 12, a P⁺⁺-type doping region 14 extending inwardly of the N-type substrate 11 from a back surface 112 of the N-type substrate 11, a N⁺⁺-type doping region 15 extending inwardly of the N-type substrate 11 from the back surface 112, a perforated dielectric layer 16 formed on the back surface 112, a P-type electrode 17 disposed on the dielectric layer 16 and extending through the dielectric layer 16 to contact the P⁺⁺-type doping region 14, and a N-type electrode 18 disposed on the dielectric layer 16 and extending through the dielectric layer 16 to contact the N⁺⁺-type doping region 15, wherein the P-type electrode 17 has a first surface 171 for contacting the P⁺⁺-type doping region 14, the N-type electrode 18 has a second surface 181 for contacting the N⁺⁺-type doping region 15, and the first surface 171, the second surface 181 and the back surface 112 are flat surface.

The P-type and N-type electrodes 17, 18 are normally formed by printing a metal paste on the dielectric surface 16, the P⁺⁺-type doping region 14 and the N⁺⁺-type doping region 15.

Applicant found that although the aforesaid conventional solar cell is provided with the anti-reflection layer 13, a significant amount of the light reflected from the first surface 171, the second surface 181 and the back surface 112 can still escape from the N-type substrate 11 through the anti-reflection layer 13, resulting in almost no light scattering and shorter light transmitting distance in the N-type substrate, thereby decreasing the utilization of the light entering from the photo-receiving surface 111 into the N-type substrate 11.

### SUMMARY OF THE INVENTION

Therefore, an object of the present invention is to provide a solar cell and a solar cell module that can overcome the aforesaid drawback associated with the prior art.

Another object of the present invention is to provide a method of making the solar cell.

According to one aspect of this invention, there is provided a solar cell that comprises: a semiconductor substrate of a crystalline silicon material having a photo-receiving surface, a back surface that is disposed opposite to said photo-receiving surface, wherein said back surface includes a roughened region; a first doped region of a first conductivity type extending inwardly of said semiconductor substrate from said back surface; a second doped region of a second conductivity type extending inwardly of said semiconductor substrate from said back surface and separated from said first doped region; a dielectric layer disposed on said back surface and having first and second through-holes corresponding respectively to said first and second doped regions; a first electrode that is disposed on said dielectric layer opposite to said back surface, and that extends through said first through-hole to contact said first doped region, wherein said first electrode has a first surface facing toward said back surface and roughened by conforming to the shape of said roughened region of said back surface; and a second electrode that is disposed on said dielectric layer opposite to said back surface, and that extends through said second through-hole to contact said second doped region, wherein said second electrode has a second surface facing toward said back surface and roughened by conforming to the shape of said roughened region of said back surface.

According to another aspect of this invention, there is provided a solar cell module that comprises: first and second panels spaced apart from each other; a plurality of solar cells disposed between said first and second panels, each of said solar cells having a structure as defined in claim 1; and an enclosure material disposed between said first and second panels and enclosing said solar cells.

According to yet another aspect of this invention, there is provided a method of making a solar cell. The method comprises: roughening a back surface of a semiconductor substrate so as to forma roughened region; forming a first doped region of a first conductivity type extending inwardly of said semiconductor substrate from said back surface; forming a second doped region of a second conductivity type extending inwardly of said semiconductor substrate from said back surface and separated from said first doped region; forming a dielectric layer on said back surface such that said dielectric layer has first and second through-holes corresponding respectively to said first and second doped regions; forming a first electrode such that said first electrode is disposed on said dielectric layer opposite to said back surface, and extends through said first through-hole to contact said first doped region, wherein said first electrode has a first surface facing toward said back surface and roughened by conforming to the shape of said roughened region of said back surface; and forming a second electrode such that said second electrode is disposed on said dielectric layer opposite to said back surface, and extends through said second through-hole to contact said second doped region, wherein said second electrode has a second surface facing toward said back surface and roughened by conforming to the shape of said roughened region of said back surface.

### BRIEF DESCRIPTION OF THE DRAWINGS

In drawings which illustrate an embodiment of the invention,

FIG. 1 is a sectional view of a conventional solar cell;

FIG. 2 is a sectional view of the preferred embodiment of a solar cell according to the present invention;

FIG. 3 is a fragmentary schematic view showing respectively the configuration of first and second surfaces of first and second electrodes of the preferred embodiment;

FIGS. 4A to 4F illustrate consecutive steps of a method of making the solar cell of the present invention;

FIGS. 5A and 5B respectively show SEM photos of a surface morphology of a conventional electrode on a non-roughened back surface of a semiconductor substrate of a conventional solar cell (Comparative Example) and an outer surface morphology of electrode (such as first or second electrode of the present invention) on a back surface of a semiconductor substrate of the preferred embodiment;

FIGS. 5C and 5D respectively show SEM photos of cross-sections of the structures of FIGS. 5A and 5B;

FIG. 6 is a plot of a reflectivity of a solar cell versus wavelength of an incident light for the solar cell of the preferred embodiment and the solar cell of Comparative Example; and

FIG. 7 is a fragmentary sectional view of a solar cell module including a plurality of solar cells, each having a structure the same as that of the preferred embodiment.

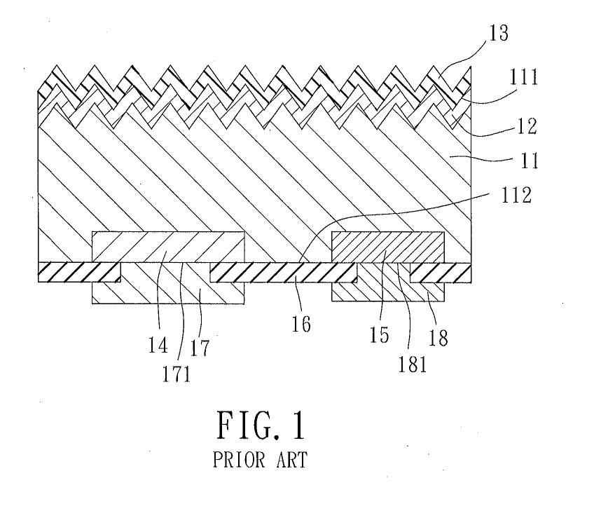

### DETAILED DESCRIPTION OF THE PREFERRED EMBODIMENT

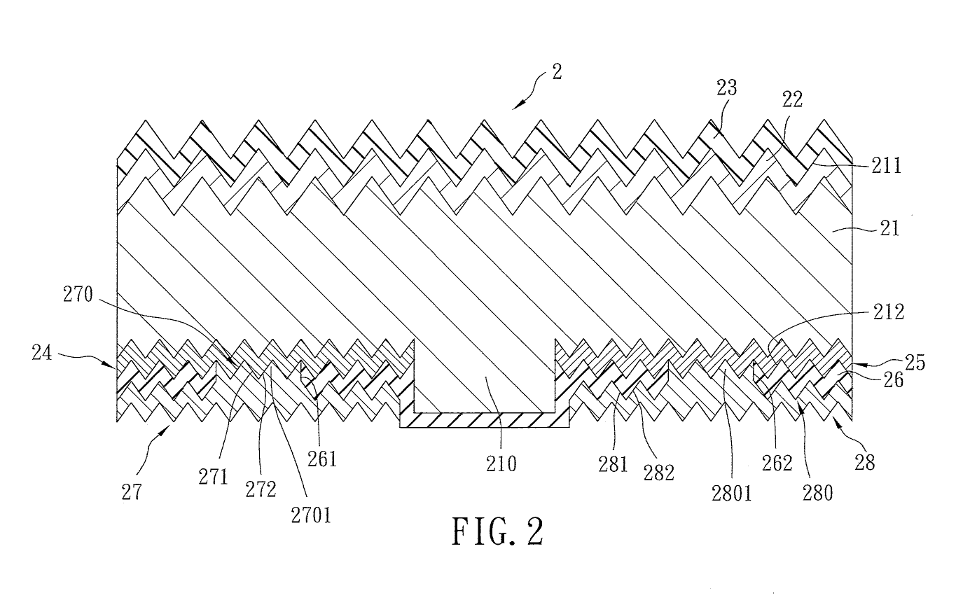

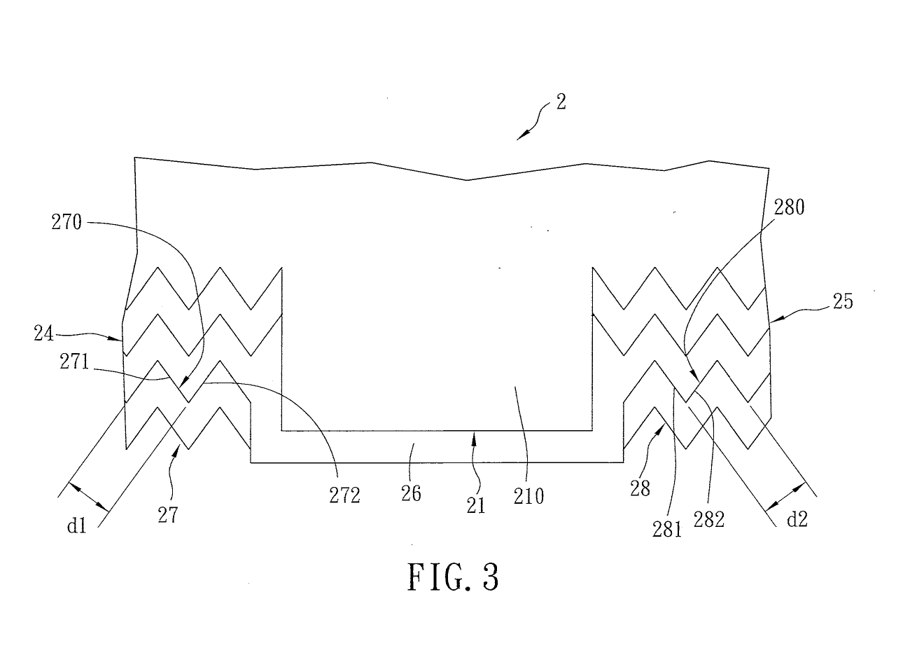

FIGS. 2 and 3 illustrate the preferred embodiment of a solar cell 2 according to the present invention. The solar cell 2 includes: a semiconductor substrate 21 of a crystalline silicon material having a photo-receiving surface 211 that is roughened to form a textured region, a back surface 212 that is disposed opposite to the photo-receiving surface 211, a partitioning region 210, a front-doping region 22 of a first conductivity type formed in the semiconductor substrate 21 and extending inwardly of the semiconductor substrate 21 from the photo-receiving surface 211, a first doped region 24 of a first conductivity type extending inwardly of the semiconductor substrate 21 from the back surface 212, and a second doped region 25 of a second conductivity type extending inwardly of the semiconductor substrate 21 from the back surface 212 and separated from the first doped region 24 by the partitioning region 210, the back surface 212 being roughened to form a roughened region. Preferably, the roughness of the roughened region of the back surface 212 is smaller than that of the textured region of the photo-receiving surface 211; a dielectric layer 26 disposed on the back surface 212 of the semiconductor substrate 21 and having first and second through-holes 261, 262 corresponding respectively to the first doped region 24 and the second doped region 25; a first electrode 27 that is disposed on the dielectric layer 26 opposite to the back surface 212 of the semiconductor substrate 21, and that extends through the first through-hole 261 to contact the first doped region 24, wherein the first electrode 27 has a first surface 270 facing toward the back surface 212 and roughened by conforming to the shape of the roughened region of the back surface 212, and the first surface 270 has a plurality of first irregularities 2701 for scattering light; and a second electrode 28 that is disposed on the dielectric layer 26 opposite to the back surface 212 of the semiconductor substrate 21, and that extends through the second through-hole 262 to contact the second doped region 25, wherein the second electrode 28 has a second surface 280 facing toward the back surface 212 and roughened by conforming to the shape of the roughened region of the back surface 212, and the second surface 280 has a plurality of second irregularities 2801 for scattering light.

In this embodiment, the first surface 270 has a plurality of first inclined planes 271 spaced from one another and second inclined planes 272 alternately disposed with the first inclined planes 271, such that each of the second inclined planes 272 is connected to and located between two adjacent ones of the first inclined planes 271. The length (d1) of the first or second inclined planes 271, 272 ranges from 0.3 μm to 10 μm. Similarly, the second surface 280 has a plurality of third inclined planes 281 spaced from one another and fourth inclined planes 282 alternately disposed with the third inclined planes 281, such that each of the fourth inclined planes 282 is connected to and located between two adjacent ones of the third inclined planes 281. The length (d2) of the third or fourth inclined planes 281, 282 ranges from 0.3 μm to 10 μm. More preferably, the length (d1, d2) of the first, second, third, or fourth inclined planes 271, 272, 281, 282 ranges from 0.5 μm to 1.1 μm.

Preferably, the first and second conductivity types are respectively N-type and P-type, and more preferably, the first and second conductivity types are respectively N⁺⁺-type (heavily doping with N-type impurities) and P⁺-type(heavily doping with P-type impurities). The semiconductor substrate 21 is N-type, and can be single-crystalline silicon or polycrystalline silicon. As such, the second doped region 25 and the semiconductor substrate 21 cooperatively form a p-n junction.

In this embodiment, the front-doping region 22 is N⁺-type and serves to forma front-side field for enhancing photo-electro conversion efficiency.

The anti-reflection layer 23 can be made from silicon nitride (SiNₓ) and serves to reduce the amount of the incident light that is reflected outwardly from the photo-receiving surface 211 of the semiconductor substrate 21 and to decrease the surface recombination velocity of the carrier.

The dielectric layer 26 can be made from oxides or nitrides and serves to decrease surface defects and the surface recombination velocity of the carrier. The first and second through-holes 261, 262 can be circular or elongate slit in shape.

The first and second electrodes 27, 28 having the first and second surfaces 270, 280 can reflect and scatter light entering from the anti-reflection layer 23 back into the semiconductor substrate 21 in different directions for utilization, thereby increasing the light travelling path in the semiconductor substrate 21 and light absorption of the semiconductor substrate 21.

Preferably, each of the first and second irregularities 2701, 2801 of the first and second surfaces 270, 280 is in the form of a protrusion that is tapered, and has top and bottom ends and a slope extending from the top end to the bottom end. The distance from the top end to the bottom end along the slope is identical with the length (d1, d2) of the first, second, third, or fourth inclined planes 271, 272, 281, 282.

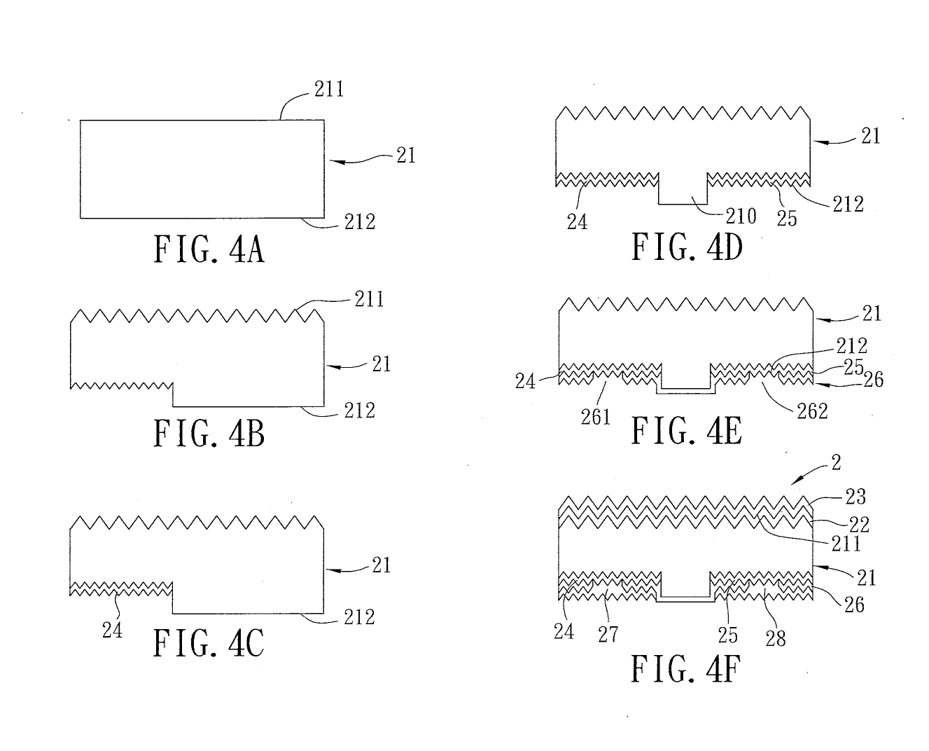

The partitioning region 210 has an outer surface. The roughness of the roughened region is larger than that of the outer surface of the partitioning region 210. FIGS. 4A to 4F illustrate consecutive steps of a method of making the solar cell 2 of the present invention. The method includes the steps of: preparing a semiconductor substrate 21 having a photo-receiving surface 211 and a back surface 212 (see FIG. 4A); roughening the photo-receiving surface 211 and a first region of the back surface 212 of the semiconductor substrate 21 by laser etching, wet etching or a combination of laser etching and wet etching so as to form a roughened region (see FIG. 4B); forming a first doped region 24 under the back surface 212 in the semiconductor substrate 21 by thermal diffusion techniques (see FIG. 4C); roughening a second region of the back surface 212 of the semiconductor substrate 21 and forming a second doped region 25 under the back surface 212 in the semiconductor substrate 21 by thermal diffusion techniques, wherein the second doped region 25 is separated from the first doped region 24 (see FIG. 4D); forming a dielectric layer 26 on the back surface 212 by PECVD techniques and forming first and second through-holes 261, 262 in the dielectric layer 26 by etching techniques such that the first and second through-holes 261, 262 correspond respectively to the first doped region 24 and the second doped region 25 (see FIG. 4E); forming a front-doping region 22 of a first conductivity type on the roughened photo-receiving surface 211 by thermal diffusion (see FIG. 4F); forming an anti-reflection layer 23 on the front-doping region 22 by PECVD techniques (see FIG. 4F); forming a first electrode 27 by printing techniques or vacuum deposition techniques such that the first electrode 27 is disposed on the dielectric layer 26 and extends through the first through-hole 261 to contact the first doped region 24 (see FIG. 4 F), wherein the first electrode 27 has a first surface 270 facing toward the back surface 212 and roughened by conforming to the shape of the roughened region of the back surface 212; and forming a second electrode 28 by printing techniques or vacuum deposition techniques such that the second electrode 28 is disposed on the dielectric layer 26 and extends through the second through-hole 262 to contact the second doped region 25, wherein the second electrode 28 has a second surface 280 facing toward the back surface 212 and roughened by conforming to the shape of the roughened region of the back surface 212 (see FIG. 4F). Preferably, formation of the first and second electrodes 27, 28 is conducted by vacuum deposition techniques, which is operated at a temperature (200° C.) much lower than a firing temperature (800-900° C.) for firing a conductive paste used in the printing techniques so as to prevent the roughened region of the back surface 212 from damage during firing process.

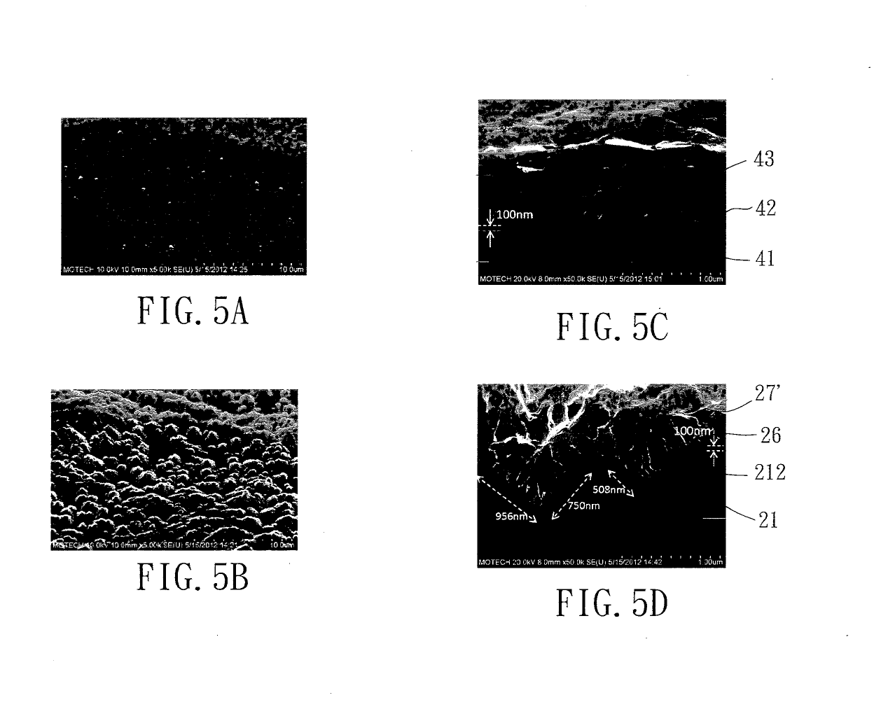

FIGS. 5A and 5B respectively show SEM photos of a surface morphology of an conventional electrode on a non-roughened back surface of a semiconductor substrate of a conventional solar cell (Comparative Example) and a surface morphology of the first irregularities of the first electrode on the back surface 212 of the semiconductor substrate 21 of the preferred embodiment. FIGS. 5C and 5D respectively show SEM photos of cross-sections of the structures of FIGS. 5A and 5B. FIG. 5C shows a flat dielectric layer 42 of the conventional solar cell (Comparative Example) having a thickness of 100 nm. In FIGS. 5D, the back surface 212 has a roughened region, the dielectric layer 26 is textured by conforming to the profile of the back surface 212, and a surface of an electrode 27′ located on the dielectric layer 26 is subsequently textured to form a roughened morphology, wherein the electrode 27′ corresponds to the first and second electrodes 27, 28 shown in FIG. 2.

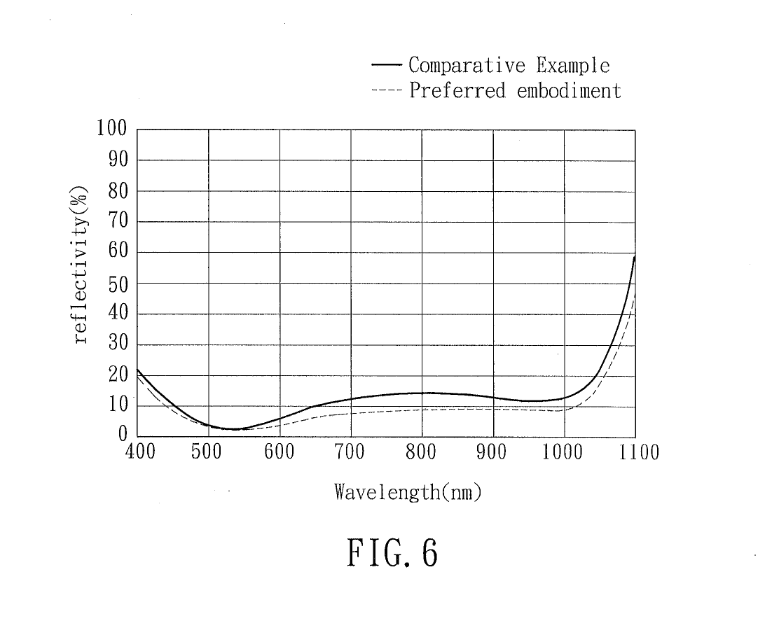

FIG. 6 is a plot of a reflectivity of a solar cell versus wavelength of an incident light for the solar cell 2 of the preferred embodiment (FIGS. 5B and 5D) and the solar cell of Comparative Example (FIGS. 5A and 5C). The reflectivity of a solar cell is determined by measuring the amount of the light reflected out of the solar cell through the anti-reflection layer. The results show that the reflectivity of the preferred embodiment is lower than that of the conventional solar cell of Comparative Example by about 5-10% when the wavelength of the incident light ranges from 600 nm to 1000 nm and about 3-5% when the wavelength of the incident light is greater than 1000 nm.

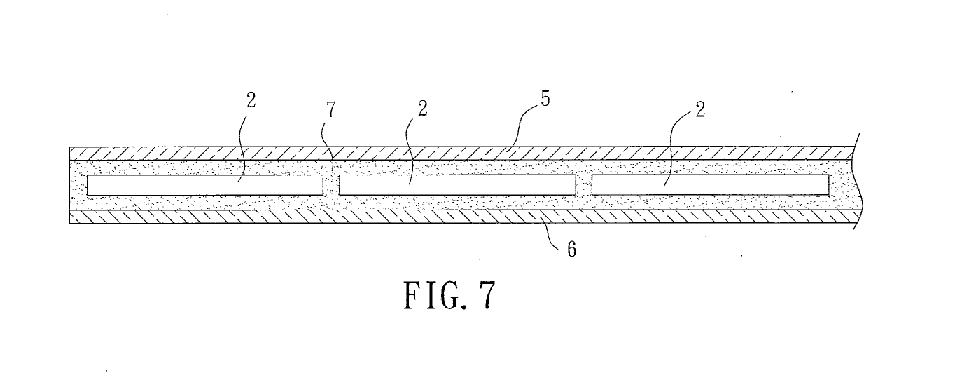

FIG. 7 illustrates a solar cell module that includes first and second panels 5, 6 spaced apart from each other; a plurality of the solar cells 2 disposed between the first and second panels 5, 6, each of the solar cells 2 having a structure the same as that of the previous embodiment; and an enclosure material 7 disposed between the first and second panels 5, 6 and enclosing the solar cells 2.

The first and second panels 5, 6 can be made from glass or plastic material. At least one of the first and second panels 5, 6 is transparent. The enclosure material 7 can be made from EVA. The solar cells 2 are electrically connected through soldering ribbons (not shown).

By forming the first and second electrodes 27, 28 with the first and second surfaces 270, 280 respectively having the first and second irregularities 2701, 2801 in the solar cell 2 of the present invention, the aforesaid light utilization drawback associated with the prior art can be alleviated.

While the present invention has been described in connection with what is considered the most practical and preferred embodiments, it is understood that this invention is not limited to the disclosed embodiment but is intended to cover various arrangements included within the spirit and scope of the broadest interpretation and equivalent arrangements.

What is claimed is:

1. A solar cell comprising:
a semiconductor substrate of a crystalline silicon material having a photo-receiving surface, a back surface that is disposed opposite to said photo-receiving surface, wherein said back surface includes a roughened region;
a first doped region of a first conductivity type extending inwardly of said semiconductor substrate from said back surface;
a second doped region of a second conductivity type extending inwardly of said semiconductor substrate from said back surface and separated from said first doped region;
a dielectric layer disposed on said back surface and having first and second through-holes corresponding respectively to said first and second doped regions;
a first electrode that is disposed on said dielectric layer opposite to said back surface, and that extends through said first through-hole to contact said first doped region, wherein said first electrode has a first surface facing toward said back surface and roughened by conforming to the shape of said roughened region of said back surface; and
a second electrode that is disposed on said dielectric layer opposite to said back surface, and that extends through said second through-hole to contact said second doped region, wherein said second electrode has a second surface facing toward said back surface and roughened by conforming to the shape of said roughened region of said back surface.

2. The solar cell according to claim 1, wherein said first surface has a plurality of first inclined planes spaced from one another and second inclined planes, each of which is located between two adjacent ones of said first inclined planes, the length of said first or second inclined planes ranging from 0.3 μm to 10 μm.

3. The solar cell according to claim 2, wherein said second surface has a plurality of third inclined planes spaced from one another and fourth inclined planes, each of which is located between two adjacent ones of said third inclined planes, the length of said third or fourth inclined planes ranging from 0.3 μm to 10 μm.

4. The solar cell according to claim 3, wherein the length of said first, second, third or fourth inclined planes ranges from 0.5 μm to 1.1 μm.

5. The solar cell according to claim 1, wherein said first and second conductivity types are respectively N-type and P-type, and said semiconductor substrate is N-type.

6. The solar cell according to claim 1, wherein said photo-receiving surface has a textured region, the roughness of said roughened region is smaller than that of said textured region of said photo-receiving surface.

7. The solar cell according to claim 1, wherein said back surface further includes a partitioning region located between said first and second doped regions and having an outer surface, the roughness of said roughened region being larger than that of said outer surface of said partitioning region.

8. A solar cell module comprising:
first and second panels spaced apart from each other;
a plurality of solar cells disposed between said first and second panels, each of said solar cells having a structure as defined in claim 1; and
an enclosure material disposed between said first and second panels and enclosing said solar cells.

9. A method of making a solar cell, comprising:
roughening a back surface of a semiconductor substrate so as to form a roughened region;
forming a first doped region of a first conductivity type extending inwardly of said semiconductor substrate from said back surface;
forming a second doped region of a second conductivity type extending inwardly of said semiconductor substrate from said back surface and separated from said first doped region;
forming a dielectric layer on said back surface such that said dielectric layer has first and second through-holes corresponding respectively to said first and second doped regions;
forming a first electrode such that said first electrode is disposed on said dielectric layer opposite to said back surface, and extends through said first through-hole to contact said first doped region, wherein said first electrode has a first surface facing toward said back surface and roughened by conforming to the shape of said roughened region of said back surface; and
forming a second electrode such that said second electrode is disposed on said dielectric layer opposite to said back surface, and extends through said second through-hole to contact said second doped region, wherein said second electrode has a second surface facing toward said back surface and roughened by conforming to the shape of said roughened region of said back surface.

10. The method according to claim 9, wherein said first surface has a plurality of first inclined planes spaced from one another and second inclined planes, each of which is located between two adjacent ones of said first inclined planes, the length of said first or second inclined planes ranging from 0.3 μm to 10 μm.

11. The method according to claim 10, wherein said second surface has a plurality of third inclined planes spaced from one another and fourth inclined planes, each of which is located between two adjacent ones of said third inclined planes, the length of said third or fourth inclined planes ranging from 0.3 μm to 10 μm.

12. The method according to claim 11, wherein the length of said first, second, third or fourth inclined planes ranges from 0.5 μm to 1.1 μm.

13. The method according to claim 9, wherein formation of said first and second electrodes is conducted by screen printing, jet printing, or vacuum deposition techniques.

14. The method according to claim 9, wherein said first and second conductivity types are respectively N-type and P-type, and said semiconductor substrate is N-type.

15. The method according to claim 10, wherein said first and second conductivity types are respectively N-type and P-type, and said semiconductor substrate is N-type.

16. The method according to claim 11, wherein said first and second conductivity types are respectively N-type and P-type, and said semiconductor substrate is N-type.

17. The method according to claim 12, wherein said first and second conductivity types are respectively N-type and P-type, and said semiconductor substrate is N-type.

18. The method according to claim 13, wherein said first and second conductivity types are respectively N-type and P-type, and said semiconductor substrate is N-type.
